(19) United States
(12) Patent Application Publication
(10) Pub. No.: US 2026/0291500 A1
(43) Pub. Date: Sep. 24, 2026

(54) LEVEL SHIFT AND DRIVER CIRCUITS WITH ELEVATED LOW-SUPPLY REFERENCES

(71) Applicant: Altera Corporation, San Jose, CA (US)

(72) Inventors: Pai Ho BONG, Bayan Lepas (MY); Seh Leong GOH, Sungai Ara (MY); Navindra NAVARATNAM, Portland, OR (US)

(21) Appl. No.: 19/087,274

(22) Filed: Mar. 21, 2025

(51) Int. Cl. H03K 19/0175; G11C 11/4093; H03K 19/173; H03K 19/20

(52) U.S. Cl. CPC H03K 19/017509; H03K 19/173; G11C 11/4093; H03K 19/20

(57) ABSTRACT

In some embodiments, level shift circuits, such as for transmitter driver circuits, include moveable low-supply reference levels that allow for high swing output capability and reduced voltage drop stress across transistors in the level shift circuit.

### TECHNICAL FIELD

Embodiments relate to the field of integrated circuits, and in particular, to level shift driver circuits.

### BRIEF DESCRIPTION OF THE DRAWINGS

The disclosure may best be understood by referring to the following description and accompanying drawings that are used to illustrate embodiments. In the drawings:

FIG. 1A is a diagram showing a portion of a conventional transmitter (Tx) for an input/output (IO) interconnect circuit.

FIG. 1B is a diagram showing a conventional Full swing level shifting P-type pre-driver circuit for high speed transmitter such as the transmitter of FIG. 1A.

FIG. 1C is a signal diagram for the circuit of FIG. 1A.

FIG. 2A is a diagram showing a portion of a transmitter circuit in accordance with some embodiments.

FIG. 2B is a signal diagram for the circuit of FIG. 2A.

FIG. 3A is a diagram of a high-side pre-drive circuit in accordance with some embodiments.

FIG. 3B is a signal diagram for the circuit of FIG. 3A in accordance with some embodiments.

FIG. 4 shows a portion of a system with interconnect circuits in accordance with some embodiments.

FIG. 5 illustrates an example computing system in accordance with some embodiments.

FIG. 6 illustrates a block diagram of an example processor that may have one or more cores and an integrated memory controller in accordance with some embodiments.

FIG. 7 is a block diagram illustrating a parallel processing computing system configured to implement one or more aspects of the examples described herein.

### DETAILED DESCRIPTION

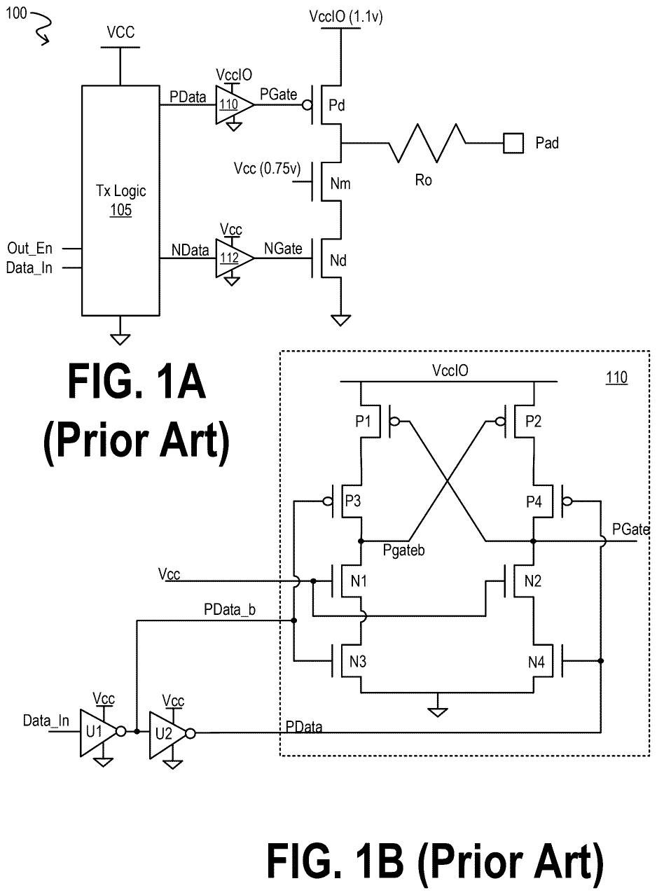

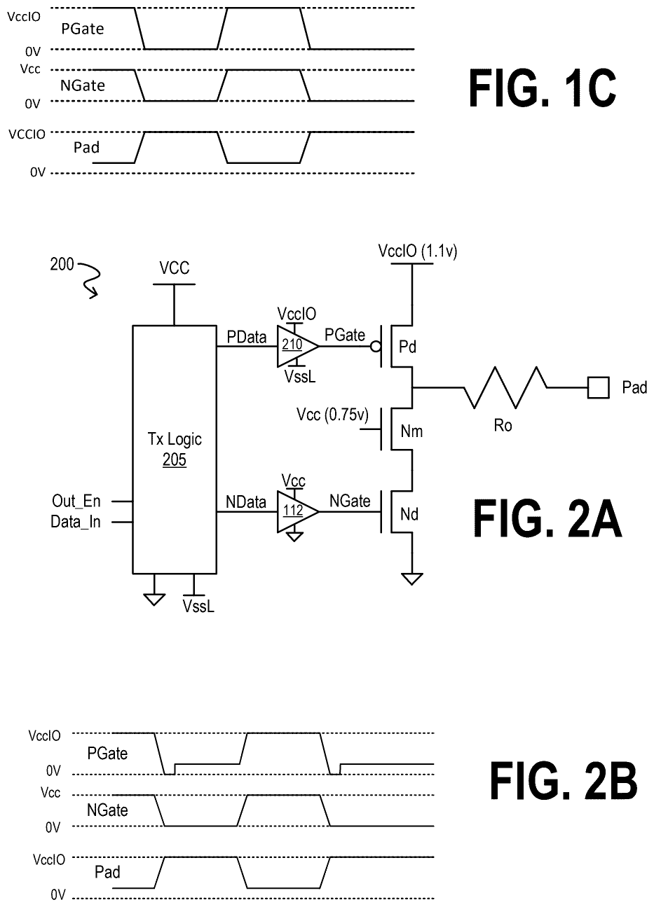

FIG. 1A is a diagram showing a portion 100 of a conventional transmitter (Tx) for an input/output (IO) interconnect circuit. For example, it may be used for a single-ended source synchronous Tx circuit such as a DDR (Double Data Rate) transmitter. The depicted transmitter circuit generates data for a single interconnect lane and includes a Tx logic block 105, pre-driver circuits 110, 112 and an output driver circuit formed from transistors Pd, Nm, and Nd, along with an output resistance Ro, all coupled together as shown. With the depicted example, the Tx logic, pre-driver inputs, and low-side drive transistor (Nd) operate at a first lower voltage range (Vss to Vcc), while the high-side transistor (Pd) operates over a larger voltage range with an upper limit of VccIO. For example, Vcc may be about 0.75 V, and VccIO may be about 1.1 V).

The transmitter circuit uses thin gate devices that should not reliably be exposed to the full swing voltage drops. Accordingly, a stack configuration is employed for the output drive transistors (Pd, Nd) with a biased-on mid-level transistor (Nm)disposed there between to protect them from full VccIO swing exposure. In this way, the smaller, thin gate, devices can be used to drive larger output swings for IO interfaces requiring larger voltage swing levels.

The Tx logic 105 is coupled to the output transistors through the pre-driver circuits (110, 112) to control the gates of the output transistors (Pd, Nd). The output drive transistors are coupled to an output node (Pad) through an output resistor (Ro), which may be a variable resistor, e.g., adjustable to 34 or 40 Ohms. Through the pre-driver circuits (110, 112), the control logic controls the output transistors (Pd, Nd) to generate an appropriate output level (e.g., 0 or VccIO) at the Pad node based on the input (Data_In) signal value.

With this example, when the input (Data_In) is low, both the PData and NData pre-drive signals will be high, resulting in the pre-driver circuits generating high signals (PGate, NGate), respectively, which causes a low to be generated at the output Pad node. Conversely, when Data_In is high (Vcc), the pre-drive inputs (PData, NData) are low, resulting in the pre-driver circuits generating low PGate, NGate signals, which cause a high to be generated at the output Pad node. This is illustrated in the signal diagram of FIG. 1C.

With this type of circuit, it's desirable for the P-type pre-driver 110 to be able to generate a full swing at its output (PGate). That is, it should be able to output a high at least approaching VccIO when turning off Pd, and it should output a low of Vss (e.g., 0 V), or at least sufficiently near Vss, when turning on the high side drive transistor (Pd). This can be challenging to achieve, however, for the P-type pre-driver 110 with the use of thin gate transistor devices, as discussed above, in view of demanding high-speed performance objectives.

FIG. 1B is a diagram showing a conventional Full swing level shifting P-type pre-driver circuit for high speed transmitter such as the transmitter of FIG. 1A. The circuit includes a full swing level shift circuit 110 and inverting control drivers (U1, U2) from the Tx logic circuitry to control the level shift circuit with differential control inputs (PData/PData_b). The level shift circuit 110 includes cross-coupled transistor branches formed from transistors P1-P4 and N1-N4 as is shown. The circuit generates an effective full-swing output (PGate) that ranges from VccIO down to Vss (e.g., ground), but unfortunately, this leaves the transistors being subjected to full VccIO/Vss swing levels when the Pd transistor is turned on, resulting in undesirable EOS (electrical over stress) exposure. It has been observed that this can cause problematic degradation over time. Other solutions such as with more robust transistor stacking have been used, but they tend to add capacitance to the output pad, which makes it difficult to achieve desired switching speeds. Accordingly, new approaches are desired.

In some embodiments, a P-type pre-driver level shift circuit is provided that uses a momentary, pulled-down, full-swing low supply reference when the P-type output drive transistor is turning on and an elevated low-supply reference to provide a reduced swing for most, if not the rest, of the time. In this way, EOS is mitigated since the level shift circuitry is only subjected to a full swing voltage drop for a relatively small part of its operational lifetime.

In some embodiments, a self-timed momentary pulled down Vss is provided and then released to reduce the swing level. In some embodiments, separate split pull-down path circuits may be used for first and second cross-coupled transistor stack branches of a level shifter. In some embodiments, the moveable vss may change, e.g., be pulled down, based on an output data state of the level shifter.

FIG. 2A is a diagram showing a portion of a transmitter circuit 200 in accordance with some embodiments. This circuit is similar to the transmitter circuit of FIG. 1, but it includes a P-type level shift circuit 210 with a moveable local low-supply reference (VssL) in place of a fixed low supply reference. In some embodiments, it also may include logic control circuitry 205 with both a fixed low supply reference (Vss) and a moveable local low supply reference (VssL). With this transmitter, the high side pre-drive level shift circuit can provide a full swing drive range to an output drive transistor for an initial turn-on duration and reduce the swing for the remaining part of the on cycle to reduce EOS subjected onto the level shift transistors. This is illustrated in the signal diagram of FIG. 2B. In some embodiments, the high-side drive transistor (Pd) gate signal is momentarily at a full swing level (VccIO/Vss) during a turn-on transition and then parked at a narrower swing level with the local low supply reference (VssL) elevated for the remaining time to reduce EOS degradation. (Note that while a P-type device is used for describing various embodiments, the disclosed pre-driver circuits could also be used for other transistor types including N-type output drive transistors operating as high side devices, for example.)

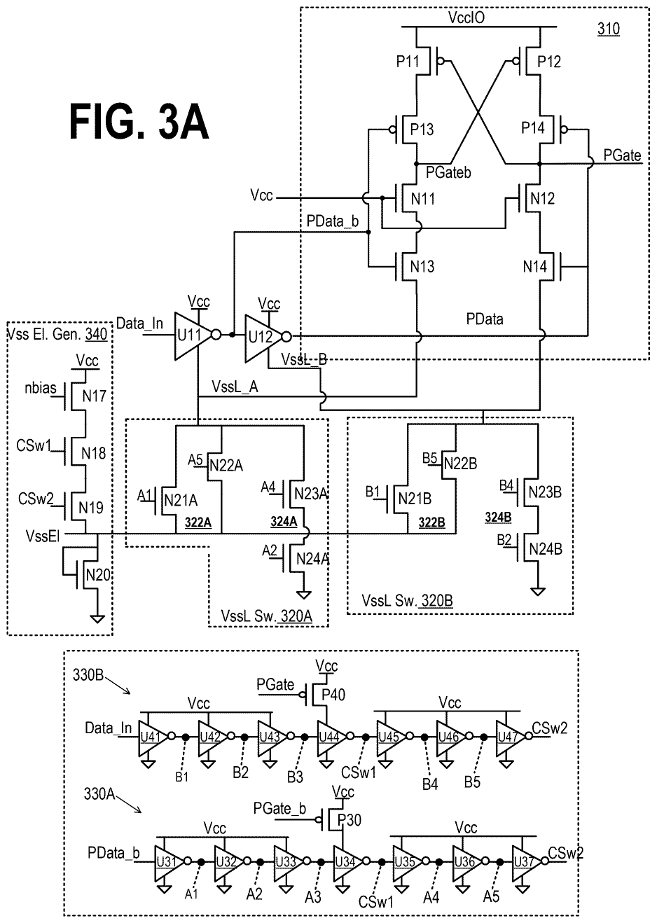

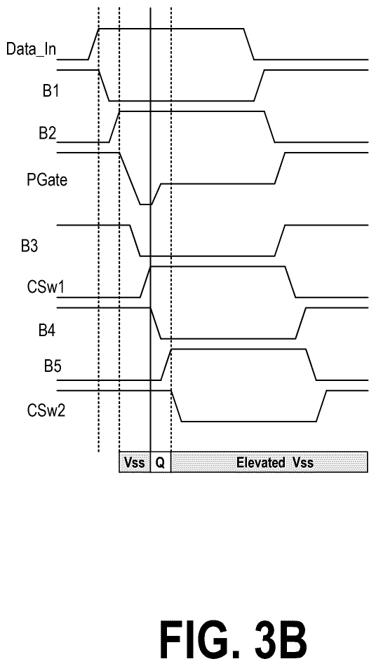

FIG. 3A is a diagram of a high-side pre-drive circuit in accordance with some embodiments. The circuit includes a level shift circuit 310, first and second local low-supply reference switch circuits 320 (320A, 320B), switch control circuits 330 (330A, 330B), and Vss elevation generator circuit 340, coupled together as shown. There are also inverting driver circuits U11, U12, which may be part of a transmitter control logic, for generating data inputs (PData, PData_b) for the level shift circuit 310, which is a differential input level shift circuit in this example.

The level shift circuit 310 may be configured similarly to the level shift circuit 110 of FIG. 1 except it employs a moveable low supply reference (VssL) instead of a fixed low-supply reference Vss. In addition, as with the depicted example, the level shift circuit 310 may use cross-coupled transistor stack branches that are split at the low-supply reference ends, although with other embodiments, the branches may use a common, but moveable, low-supply reference.

As shown in the figure, the level shift circuit 310 includes a first transistor stack branch formed from transistors P11, P13, N11, and N13 that is cross-coupled to a second branch formed from transistors P12, P14, N12, and N14, as is shown. Both the first and second branches are coupled to a common high supply reference (VccIO), e.g., 1 V or higher, but the first branch is coupled to a first local low-supply reference (VssL_A) from the first local Vss switch circuit 320A, and the second branch is coupled to a second local low-supply reference (VssL_B) from the second local Vss switch circuit 320B. Both the first and second local Vss switch circuits are coupled to a first low-supply reference (Vss) and to a second, elevated low-supply reference (VssEl) that is higher than the first low-supply reference (Vss, e.g., ground). The second, elevated low-supply reference (VssEl) is generated by circuit 340.

The elevated local Vss reference generator 340 includes N-type transistors N17-N20, as shown, to generate the elevated Vss voltage level (VssEl). N17 sets a bias current level, and transistors N18, N19 operate as switches controlled by the control circuits 330A, 330B to charge the VssEl node. Transistor N20 is configured as a diode to generate a threshold level voltage at the VssEl node when the switch transistors N18, N19 are turned on.

The local low-supply reference switch circuits (320A, 320B) are coupled to their associated local low-supply reference nodes VssL_A, VssL_B, respectively, to provide them with a reference level of either Vss (e.g., ground) or VssEl. The applied value depends on the states of the control signals from their associated control circuits (330A, 330B) respectively.

(Note that for convenience, only the circuitry with regard to the PGate branch (320B, 330B) will be discussed, but it should be appreciated that the other branch operates in the same manner except that its control inputs are complements of those of the other branch. That is, control circuit 330A operates off of PGate_b and PData_b rather than PGate and Data_In, as is shown in the figure. Along these lines, it should also be appreciated that in some embodiments, both local Vss switches need not be used, depending on design considerations. For example, in some embodiments, only the branch circuitry corresponding to the gate drive, e.g., PGate, used for the output drive transistors may be employed. Alternatively, in some embodiments, the complementary branches may not even be split. That is, they may use a common local low-supply reference controlled by a local supply reference switch such as switch 320A or 320B. Moreover, in some embodiments, when both switch circuits are used, both high-side gate signals, PGate and PGateb, may be used to drive separate, complementary, high-side drive transistors.)

Local Vss switch 320B includes an OR switch 322B and an AND switch 324B. The OR switch is formed from N-type transistors N21B, N22B, while the AND switch 324B is formed from N-type transistors N23B, N24B, coupled together as shown. With additional reference to control circuit 330B, elevated Vss generator circuit 340 and signal diagram 3B, the OR (322B) and AND (324B) transistors, along with switch transistors N18, N19 are controlled by control signals (B1-B5, CSw1, CSw2) from control circuit 330B as shown.

The control circuit includes inverters U41-U47 to generate the signals in the indicated order based on the input (Data_In) value and the PGate signal value, which controls power to U44 through switch P40. When Data_In goes high, B1 goes low, causing B2 to go high. With Data_In having gone high, PGate will transition low, which turns on P40, causing B4, B5, CSw1, and CSw2 to transition as indicated in the signal diagram of FIG. 3B. As can be seen, the AND switch (324B) controls (B2, B4) are both high for a small duration upon the PGate transitioning low. This causes the local Vss (VssL_B) to be pulled down to Vss until B4 goes Low. The elevated Vss generation circuit is switched on to charge the VssEl node, which is coupled through to the local Vss node (VssL_B) through the OR switch 322B. This level is maintained until the next PGate transition from high to low.

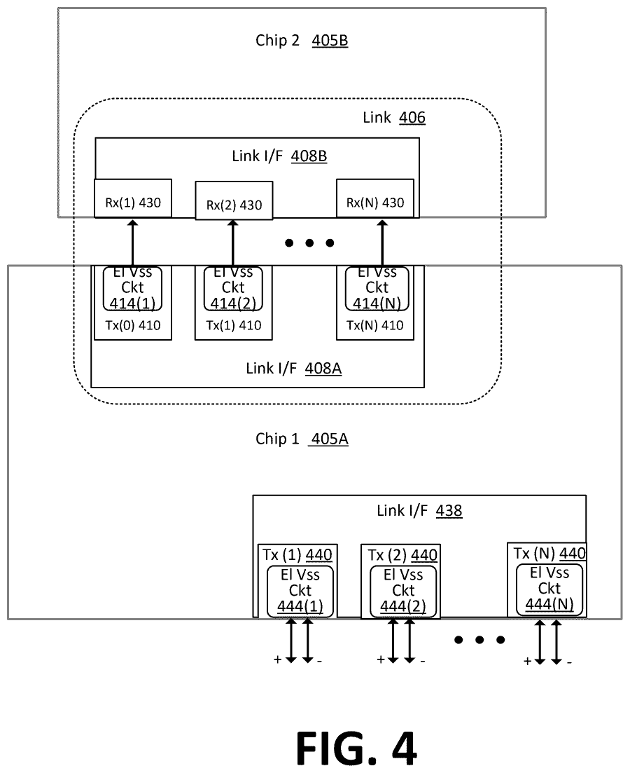

FIG. 4 shows a portion of a system with interconnect interface circuits in accordance with some embodiments. The system includes a first chip (Chip 1, 405A) and a second chip (Chip 2, 405B), coupled together through a chip-to-chip (C2C) link (or interconnect) 406.

The depicted link comprises a first link interface (I/F) 408A, which is part of the first chip 405A, coupled through a plurality of channel pathways (indicated with arrows) to a corresponding second link I/F 408B, which is part of the second chip 405B. (Note that for simplicity and ease of understanding, while the link 406 may be bi-directional, only part of it is shown for transmissions from the first to the second chip.)

The first link I/F 408A includes a plurality of transmitter circuits 410 (Tx(1)-Tx(N)) configured to be coupled with corresponding receivers 430, which are part of the second link I/F 408B, through channel paths. Each of the transmitters 410 includes a transmitter driver circuit (not shown) including associated elevated Vss circuits 414 in accordance with any of the embodiments described herein. The Tx driver circuits, for example, may be implemented with pre driver circuits with level shift circuits including elevated Vss circuits as described herein. The links may correspond to any suitable interconnect types such as source synchronous links such as DDR links.

The first chip (405A) also includes an additional link interface 438 such as an off-package link interface (e.g., PCIe or DDR) to couple with a corresponding link interface counterpart from another chip package. Link I/F 438 includes single-ended or differential (as is indicated in this example) transmitter circuits 440 (Tx1-TxN) that each include a pair of complementary Tx driver circuits (not shown) for wireline communications. Each transmitter 440 also includes elevated Vss circuits 444, as disclosed herein, to provide EOS relief for thin gate transistors used in IO circuits for the Tx drivers. These link interface examples may be employed in any of the system examples described in the following sections.

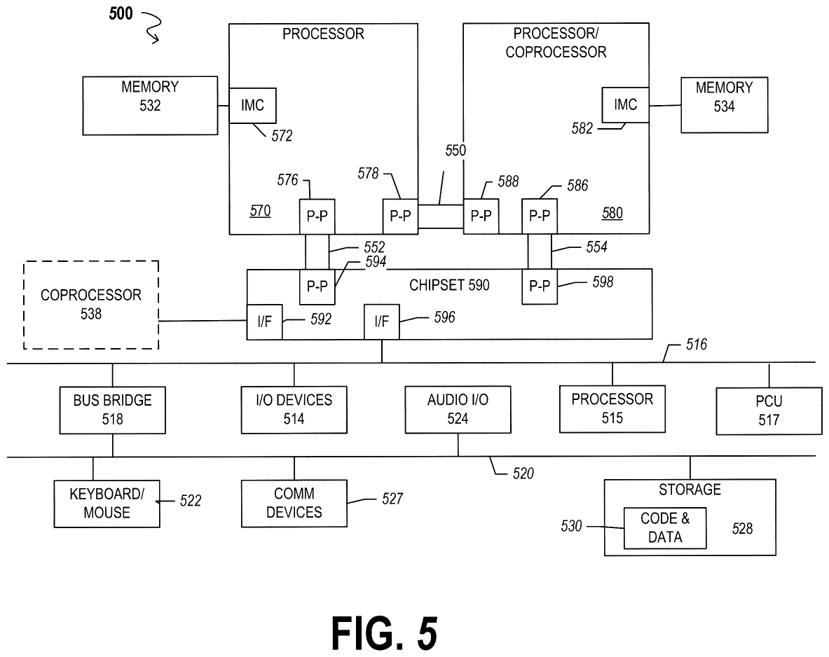

FIG. 5 illustrates an example computing system including transmit driver circuits with moveable low-supply references in accordance with some embodiments. Multiprocessor system 500 is an interfaced system and includes a plurality of processors including a first processor 570 and a second processor 580 coupled via an interface 550 such as a point-to-point (P-P) interconnect, a fabric, and/or bus. In some examples, the first processor 570 and the second processor 580 are homogeneous. In some examples, first processor 570 and the second processor 580 are heterogenous. Though the example system 500 is shown to have two processors, the system may have three or more processors, or may be a single processor system. In some examples, the computing system is implemented, wholly or partially, with a system on a chip (SoC) or a multi-chip (or multi-chiplet) module, in the same or in different package combinations.

Processors 570 and 580 are shown including integrated memory controller (IMC) circuitry 572 and 582, respectively. Processor 570 also includes interface circuits 576 and 578, along with core sets. Similarly, second processor 580 includes interface circuits 586 and 588, along with a core set as well. A core set generally refers to one or more compute cores that may or may not be grouped into different clusters, hierarchal groups, or groups of common core types. Cores may be configured differently for performing different functions and/or instructions at different performance and/or power levels. The processors may also include other blocks such as memory and other processing unit engines.

Processors 570, 580 may exchange information via the interface 550 using interface circuits 578, 588. IMCs 572 and 582 couple the processors 570, 580 to respective memories, namely a memory 532 and a memory 534, which may be portions of main memory locally attached to the respective processors.

Processors 570, 580 may each exchange information with a network interface (NW I/F) 590 via individual interfaces 552, 554 using interface circuits 576, 594, 586, 598. The network interface 590 (e.g., one or more of an interconnect, bus, and/or fabric, and in some examples is a chipset) may optionally exchange information with a coprocessor 538 via an interface circuit 592. In some examples, the coprocessor 538 is a special-purpose processor, such as, for example, a high-throughput processor, a network or communication processor, compression engine, graphics processor, general purpose graphics processing unit (GPGPU), neural-network processing unit (NPU), embedded processor, or the like.

A shared cache (not shown) may be included in either processor 570, 580 or outside of both processors, yet connected with the processors via an interface such as P-P interconnect, such that either or both processors'local cache information may be stored in the shared cache if a processor is placed into a low power mode.

Network interface 590 may be coupled to a first interface 516 via interface circuit 596. In some examples, first interface 516 may be an interface such as a Peripheral Component Interconnect (PCI) interconnect, a PCI Express interconnect, or another I/O interconnect. In some examples, first interface 516 is coupled to a power control unit (PCU) 517, which may include circuitry, software, and/or firmware to perform power management operations with regard to the processors 570, 580 and/or co-processor 538. PCU 517 provides control information to one or more voltage regulators (not shown) to cause the voltage regulator(s) to generate the appropriate regulated voltage(s). PCU 517 also provides control information to control the operating voltage generated. In various examples, PCU 517 may include a variety of power management logic units (circuitry) to perform hardware-based power management. Such power management may be wholly processor controlled (e.g., by various processor hardware, and which may be triggered by workload and/or power, thermal or other processor constraints) and/or the power management may be performed responsive to external sources (such as a platform or power management source or system software).

PCU 517 is illustrated as being present as logic separate from the processor 570 and/or processor 580. In other cases, PCU 517 may execute on a given one or more of cores (not shown) of processor 570 or 580. In some cases, PCU 517 may be implemented as a microcontroller (dedicated or general-purpose) or other control logic configured to execute its own dedicated power management code, sometimes referred to as P-code. In yet other examples, power management operations to be performed by PCU 517 may be implemented externally to a processor, such as by way of a separate power management integrated circuit (PMIC) or another component external to the processor. In yet other examples, power management operations to be performed by PCU 517 may be implemented within BIOS or other system software. Along these lines, power management may be performed in concert with other power control units implemented autonomously or semi-autonomously, e.g., as controllers or executing software in cores, clusters, IP blocks and/or in other parts of the overall system.

Various I/O devices 514 may be coupled to first interface 516, along with a bus bridge 518 which couples first interface 516 to a second interface 520. In some examples, one or more additional processor(s) 515, such as coprocessors, high throughput many integrated core (MIC) processors, GPGPUs, accelerators (such as graphics accelerators or digital signal processing (DSP) units), field programmable gate arrays (FPGAs), or any other processor, are coupled to first interface 516. In some examples, second interface 520 may be a low pin count (LPC) interface. Various devices may be coupled to second interface 520 including, for example, a keyboard and/or mouse 522, communication devices 527 and storage circuitry 528. Storage circuitry 528 may be one or more non-transitory machine-readable storage media as described below, such as a disk drive or other mass storage device which may include instructions/code and data 530 and may implement the storage in some examples. Further, an audio I/O 524 may be coupled to second interface 520. Note that other architectures than the point-to-point architecture described above are possible. For example, instead of the point-to-point architecture, a system such as multiprocessor system 500 may implement a multi-drop interface or other such architecture.

Processor cores may be implemented in different ways, for different purposes, and in different processors. For instance, implementations of such cores may include: 1) a general purpose in-order core intended for general-purpose computing; 2) a high-performance general purpose out-of-order core intended for general-purpose computing; 3) a special purpose core intended primarily for graphics and/or scientific (throughput) computing. Implementations of different processors may include: 1) a CPU including one or more general purpose in-order cores intended for general-purpose computing and/or one or more general purpose out-of-order cores intended for general-purpose computing; and 2) a coprocessor including one or more special purpose cores intended primarily for graphics and/or scientific (throughput) computing. Such different processors lead to different computer system architectures, which may include: 1) the coprocessor on a separate chip from the CPU; 2) the coprocessor on a separate die in the same package as a CPU; 3) the coprocessor on the same die as a CPU (in which case, such a coprocessor is sometimes referred to as special purpose logic, such as integrated graphics and/or scientific (throughput) logic, or as special purpose cores); and 4) a system on a chip (SoC) that may be included on the same die as the described CPU (sometimes referred to as the application core(s) or application processor(s)), the above described coprocessor, and additional functionality. Example core architectures are described next, followed by descriptions of example processors and computer architectures.

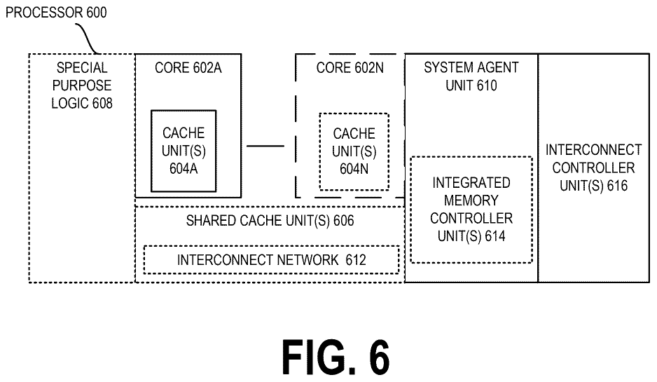

FIG. 6 illustrates a block diagram of an example processor 600 that may have one or more cores and an integrated memory controller in accordance with some embodiments. The solid lined boxes illustrate a processor and/or SoC 600 with a single core 602(A), system agent unit circuitry 610, and a set of one or more interface controller unit(s) circuitry 616, while the optional addition of the dashed lined boxes illustrates an alternative processor and/or SoC 600 with multiple cores 602(A)-(N), a set of one or more integrated memory controller unit(s) circuitry 614 in the system agent unit circuitry 610, and special purpose logic 608, as well as a set of one or more interface controller unit(s) circuitry 616. Note that the processor and/or SoC 600 may be one of the processors 570 or 580, or co-processor 538 or 515 of FIG. 5.

Thus, different implementations of the processor and/or SoC 600 may include: 1) a CPU with the special purpose logic 608 being a high-throughput processor, a network or communication processor, a compression engine, a graphics processor, a general purpose graphics processing unit (GPGPU), a neural-network processing unit (NPU), an embedded processor, a security processor, a matrix accelerator, an in-memory analytics accelerator, a compression accelerator, a data streaming accelerator, data graph operations, or the like(which may include one or more cores, not shown), and the cores 602(A)-(N) being one or more general purpose cores (e.g., general purpose in-order cores, general purpose out-of-order cores, or a combination of the two); 2) a co-processor with the cores 602(A)-(N) being a large number of special purpose cores intended primarily for graphics and/or scientific (throughput); and 3) a co-processor with the cores 602(A)-(N) being a large number of general purpose in-order cores. Thus, the processor and/or SoC 600 may be a general-purpose processor, co-processor or special-purpose processor, such as, for example, a network or communication processor, compression engine, graphics processor, GPGPU (general purpose graphics processing unit), a high throughput many integrated core (MIC) co-processor (including 30 or more cores), embedded processor, or the like. The processor may be implemented on one or more chips. The processor and/or SoC 600 may be a part of and/or may be implemented on one or more substrates using any of a number of process technologies, such as, for example, complementary metal oxide semiconductor (CMOS), bipolar CMOS (BiCMOS), P-type metal oxide semiconductor (PMOS), or N-type metal oxide semiconductor (NMOS).

A memory hierarchy includes one or more levels of cache unit(s) circuitry 604(A)-(N) within the cores 602(A)-(N), a set of one or more shared cache unit(s) circuitry 606, and external memory (not shown) coupled to the set of integrated memory controller unit(s) circuitry 614. The set of one or more shared cache unit(s) circuitry 606 may include one or more mid-level caches, such as level 2 (L2), level 3 (L3), level 4 (L4), or other levels of cache, such as a last level cache (LLC), and/or combinations thereof. While in some examples interface network circuitry 612 (e.g., a ring interconnect) interfaces the special purpose logic 608 (e.g., integrated graphics logic), the set of shared cache unit(s) circuitry 606, and the system agent unit circuitry 610, alternative examples use any number of well-known techniques for interfacing such units. In some examples, coherency is maintained between one or more of the shared cache unit(s) circuitry 606 and cores 602(A)-(N). In some examples, interface controller unit(s) circuitry 616 couple the cores 602(A)-(N) to one or more other devices 618 such as one or more I/O devices, storage, one or more communication devices (e.g., wireless networking, wired networking, etc.), etc.

In some examples, one or more of the cores 602(A)-(N) are capable of multi-threading. The system agent unit circuitry 610 includes those components coordinating and operating cores 602(A)-(N). The system agent unit circuitry 610 may include, for example, power control unit (PCU) circuitry and/or display unit circuitry (not shown). The PCU may be or may include logic and components needed for regulating the power state of the cores 602(A)-(N) and/or the special purpose logic 608 (e.g., integrated graphics logic). The display unit circuitry is for driving one or more externally connected displays.

The cores 602(A)-(N) may be homogenous in terms of instruction set architecture (ISA). Alternatively, the cores 602(A)-(N) may be heterogeneous in terms of ISA; that is, a subset of the cores 602(A)-(N) may be capable of executing an ISA, while other cores may be capable of executing only a subset of that ISA or another ISA.

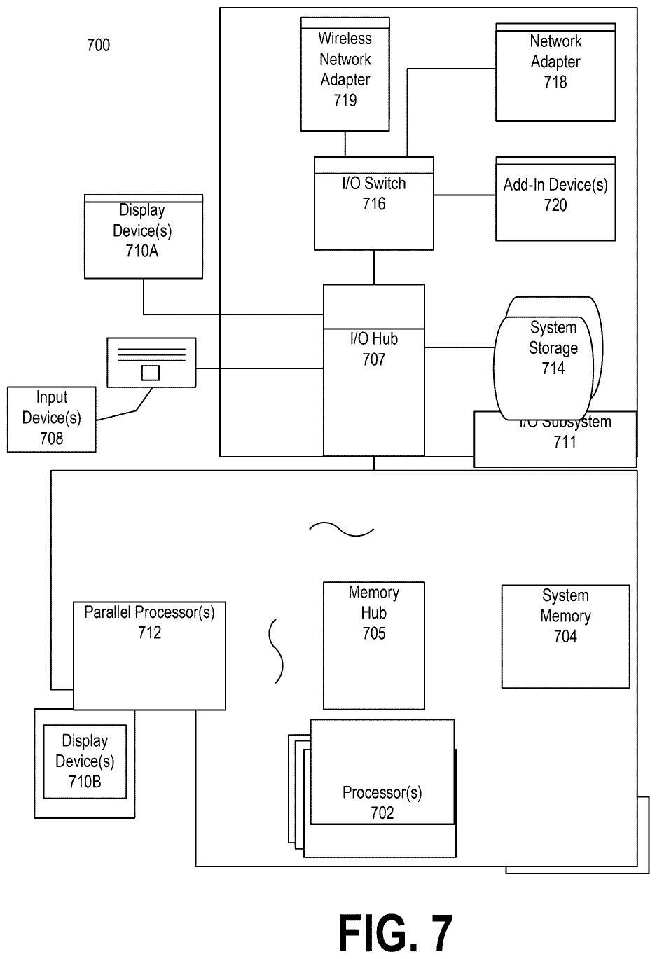

FIG. 7 is a block diagram illustrating a parallel processing computing system 700 configured to implement one or more aspects of the examples described herein. The computing system 700 includes a processing subsystem 701 having one or more processor(s) 702 and a system memory 704 communicating via an interconnection path that may include a memory hub 705. The memory hub 705 may be a separate component within a chipset component or may be integrated within the one or more processor(s) 702. The memory hub 705 couples with an I/O subsystem 711 via a communication link 706. The I/O subsystem 711 includes an I/O hub 707 that can enable the computing system 700 to receive input from one or more input device(s) 708. Additionally, the I/O hub 707 can enable a display controller, which may be included in the one or more processor(s) 702, to provide outputs to one or more display device(s) 710A. In some examples the one or more display device(s) 710A coupled with the I/O hub 707 can include a local, internal, or embedded display device.

The processing subsystem 701, for example, includes one or more parallel processor(s) 712 coupled to memory hub 705 via a bus or communication link 713. The communication link 713 may be one of any number of standards-based communication link technologies or protocols, such as, but not limited to PCI Express, or may be a vendor specific communications interface or communications fabric. The one or more parallel processor(s) 712 may form a computationally focused parallel or vector processing system that can include a large number of processing cores and/or processing clusters, such as a many integrated core (MIC) processor. For example, the one or more parallel processor(s) 712 form a graphics processing subsystem that can output pixels to one of the one or more display device(s) 710A coupled via the I/O hub 707. The one or more parallel processor(s) 712 can also include a display controller and display interface (not shown) to enable a direct connection to one or more display device(s) 710B.

Within the I/O subsystem 711, a system storage unit 714 can connect to the I/O hub 707 to provide a storage mechanism for the computing system 700. An I/O switch 716 can be used to provide an interface mechanism to enable connections between the I/O hub 707 and other components, such as a network adapter 718 and/or wireless network adapter 719 that may be integrated into the platform, and various other devices that can be added via one or more add-in device(s) 720. The add-in device(s) 720 may also include, for example, one or more external graphics processor devices, graphics cards, and/or compute accelerators. The network adapter 718 can be an Ethernet adapter or another wired network adapter. The wireless network adapter 719 can include one or more of a Wi-Fi, Bluetooth, near field communication (NFC), or other network device that includes one or more wireless radios.

The computing system 700 can include other components not explicitly shown, including USB or other port connections, optical storage drives, video capture devices, and the like, which may also be connected to the I/O hub 707. Communication paths interconnecting the various components in FIG. 7 may be implemented using any suitable protocols, such as PCI (Peripheral Component Interconnect) based protocols (e.g., PCI-Express), or any other bus or point-to-point communication interfaces and/or protocol(s), such as the NVLink high-speed interconnect, Compute Express Link™ (CXL™) (e.g., CXL. mem), Infinity Fabric (IF), Ethernet (IEEE 802.3), remote direct memory access (RDMA), InfiniBand, Internet Wide Area RDMA Protocol (iWARP), Transmission Control Protocol (TCP), User Datagram Protocol (UDP), quick UDP Internet Connections (QUIC), RDMA over Converged Ethernet (RoCE), Intel QuickPath Interconnect (QPI), Intel Ultra Path Interconnect (UPI), Intel On-Chip System Fabric (IOSF), Omnipath, HyperTransport, Advanced Microcontroller Bus Architecture (AMBA) interconnect, OpenCAPI, Gen-Z, Cache Coherent Interconnect for Accelerators (CCIX), 3GPP Long Term Evolution (LTE) (4G), 3GPP 5G, and variations thereof, or wired or wireless interconnect protocols known in the art. In some examples, data can be copied or stored to virtualized storage nodes using a protocol such as non-volatile memory express (NVMe) over Fabrics (NVMe-oF) or NVMe.

The one or more parallel processor(s) 712 may incorporate circuitry optimized for graphics and video processing, including, for example, video output circuitry, and constitutes a graphics processing unit (GPU). Alternatively or additionally, the one or more parallel processor(s) 712 can incorporate circuitry optimized for general purpose processing, while preserving the underlying computational architecture, described in greater detail herein. Components of the computing system 700 may be integrated with one or more other system elements on a single integrated circuit. For example, the one or more parallel processor(s) 712, memory hub 705, processor(s) 702, and I/O hub 707 can be integrated into a system on chip (SoC) integrated circuit. Alternatively, the components of the computing system 700 can be integrated into a single package to form a system in package (SIP) configuration. In some examples at least a portion of the components of the computing system 700 can be integrated into a multi-chip module (MCM), which can be interconnected with other multi-chip modules into a modular computing system.

It will be appreciated that the computing system 700 shown herein is illustrative and that variations and modifications are possible. The connection topology, including the number and arrangement of bridges, the number of processor(s) 702, and the number of parallel processor(s) 712, may be modified as desired. For instance, system memory 704 can be connected to the processor(s) 702 directly rather than through a bridge, while other devices communicate with system memory 704 via the memory hub 705 and the processor(s) 702. In other alternative topologies, the parallel processor(s) 712 are connected to the I/O hub 707 or directly to one of the one or more processor(s) 702, rather than to the memory hub 705. In other examples, the I/O hub 707 and memory hub 705 may be integrated into a single chip. It is also possible that two or more sets of processor(s) 702 are attached via multiple sockets, which can couple with two or more instances of the parallel processor(s) 712.

Some of the particular components shown herein are optional and may not be included in all implementations of the computing system 700. For example, any number of add-in cards or peripherals may be supported, or some components may be eliminated. Furthermore, some architectures may use different terminology for components similar to those illustrated in FIG. 7. For example, the memory hub 705 may be referred to as a Northbridge in some architectures, while the I/O hub 707 may be referred to as a Southbridge.

Illustrative examples of the technologies disclosed herein are provided below. An embodiment of the technologies may include any one or more, and any compatible combination of, the examples described below.

Example 1 is an apparatus that includes a level shift circuit and a local low-supply reference switch circuit. The level shift circuit includes a local low-supply reference node and an input node. The local reference switch circuit is coupled to the local low-supply reference node to provide a first low-supply reference level responsive to the input node transitioning from a first logic state to a second logic state and to provide a second low-supply reference level thereafter before the input node transitions back to the first logic state, and the second low-supply reference level is higher than the first low-supply reference level.

Example 2 includes the subject matter of example 1, and wherein the local reference switch circuit is coupled to a ground node for the first low-supply reference level.

Example 3 includes the subject matter of any of examples 1-2, and wherein the local reference switch circuit is coupled to an elevated reference generation circuit for the second low-supply reference level.

Example 4 includes the subject matter of any of examples 1-3, and wherein the elevated reference generation circuit includes a diode-connected transistor to generate the second low-supply reference level.

Example 5 includes the subject matter of any of examples 1-4, and wherein the local reference switch circuit includes an AND circuit coupled between the ground node and the local low-supply reference node.

Example 6 includes the subject matter of any of examples 1-5, and wherein the local reference switch circuit includes an OR circuit coupled between the local low-supply reference node and the elevated reference generation circuit.

Example 7 includes the subject matter of any of examples 1-6, and comprising a control circuit including two or more sequentially-coupled delay circuits coupled to the local reference switch circuit to control whether the first or second low-supply reference level is provided to the local low-supply reference node.

Example 8 includes the subject matter of any of examples 1-7, and wherein the local reference switch circuit is a first local reference switch circuit coupled to a first branch of the level shift circuit, the apparatus comprising a second local reference switch circuit coupled to a second branch of the level shift circuit.

Example 9 includes the subject matter of any of examples 1-8, and wherein the first and second branches are to provide complementary gate drive output signals.

Example 10 is an apparatus that includes an IO interconnect circuit. The IO interconnect circuit includes at least one transmitter circuit that includes a pre-driver circuit with an input node to receive an input signal with a first high-supply reference limit and an output node coupled to a high-side output transistor. The output node is to provide a drive signal with a second high-side reference limit that is higher than the first high-side reference limit. The pre-driver circuit includes a level shift circuit with a moveable low-supply reference that is to pull down to a first low-supply reference level from a second low-supply reference level when the drive signal transitions to a low state.

Example 11 includes the subject matter of example 10, and wherein the IO interconnect is part of a double-data rate (DDR) link interface in a field programmable gate array (FPGA) device.

Example 12 includes the subject matter of any of examples 10-11, and wherein the pre-driver circuit includes a local reference switch circuit coupled to provide the moveable low-supply reference and is coupled to a ground node for the first low-supply reference level.

Example 13 includes the subject matter of any of examples 10-12, and wherein the local reference switch circuit is coupled to an elevated reference generation circuit for the second low-supply reference level.

Example 14 includes the subject matter of any of examples 10-13, and wherein the elevated reference generation circuit includes a diode-connected transistor to generate the second low-supply reference level.

Example 15 includes the subject matter of any of examples 10-14, and wherein the local reference switch circuit includes an AND circuit coupled between the ground node and the moveable low-supply reference.

Example 16 includes the subject matter of any of examples 10-15, and wherein the local reference switch circuit includes an OR circuit coupled between the moveable low-supply reference and the elevated reference generation circuit.

Example 17 includes the subject matter of any of examples 10-16, and comprising a control circuit including two or more sequentially-coupled delay circuits coupled to the local reference switch circuit to control whether the first or second low-supply reference level is provided to the moveable low-supply reference.

Example 18 includes the subject matter of any of examples 10-17, and wherein the local reference switch circuit is a first local reference switch circuit coupled to a first branch of the level shift circuit, the apparatus comprising a second local reference switch circuit coupled to a second branch of the level shift circuit.

Example 19 includes the subject matter of any of examples 10-18, and wherein the first and second branches are to provide complementary gate drive output signals.

Example 20 is a system that includes first and second ICs. The first IC includes a first interconnect circuit with at least one transmitter circuit that includes: (i) a level shift circuit including a local low-supply reference node and an input node, and (ii) a local reference switch circuit coupled to the local low-supply reference node to provide a first low-supply reference level responsive to the input node transitioning from a first logic state to a second logic state and to provide a second low-supply reference level thereafter before the input node transitions back to the first logic state. The second low-supply reference level is higher than the first low-supply reference level. The second IC includes a second interconnect with at least one receiver circuit coupled to the at least one transmitter circuit.

Example 21 includes the subject matter of example 20, and wherein the first and second interconnect circuits form a double-data rate (DDR) link, and the second IC is a memory device.

Example 22 includes the subject matter of any of examples 20-21, and wherein the local reference switch circuit is coupled to a ground node for the first low-supply reference level, and the local reference switch circuit is coupled to an elevated reference generation circuit for the second low-supply reference level.

Example 23 includes the subject matter of any of examples 20-22, and wherein the elevated reference generation circuit includes a diode-connected transistor to generate the second low-supply reference level.

Example 24 includes the subject matter of any of examples 20-23, and wherein the local reference switch circuit includes an AND circuit coupled between the ground node and the local low-supply reference node.

Example 25 includes the subject matter of any of examples 20-24, and wherein the local reference switch circuit includes an OR circuit coupled between the local low-supply reference node and the elevated reference generation circuit.

Example 26 includes the subject matter of any of examples 20-25, and comprising a control circuit including two or more sequentially-coupled delay circuits coupled to the local reference switch circuit to control whether the first or second low-supply reference level is provided to the local low-supply reference node.

Example 27 includes the subject matter of any of examples 20-26, and wherein the local reference switch circuit is a first local reference switch circuit coupled to a first branch of the level shift circuit, the apparatus comprising a second local reference switch circuit coupled to a second branch of the level shift circuit.

Example 28 includes the subject matter of any of examples 20-27, and wherein the first and second branches are to provide complementary gate drive output signals.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, or magnetic connection between the things that are connected or an indirect connection, through one or more passive or active intermediary devices.

The term “circuit” or “module” may refer to one or more passive and/or active components that are arranged to cooperate with one another to provide a desired function. It should be appreciated that different circuits or modules may consist of separate components, they may include both distinct and shared components, or they may consist of the same components. For example, A controller circuit may be a first circuit for performing a first function, and at the same time, it may be a second controller circuit for performing a second function, related or not related to the first function.

The meaning of “in” includes “in” and “on” unless expressly distinguished for a specific description.

The terms “substantially,” “close,” “approximately,” “near,” and “about,” unless otherwise indicated, generally refer to being within +/−10% of a target value.

Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

It is pointed out that those elements of the figures having the same reference numbers (or names) as the elements of any other figure can operate or function in any manner similar to that described but are not limited to such.

For purposes of the embodiments, unless expressly described differently, the transistors in various circuits and logic blocks described herein may be implemented with any suitable transistor type such as field effect transistors (FETs) or bipolar type transistors. FET transistor types may include but are not limited to metal oxide semiconductor (MOS) type FETs such as tri-gate, FinFET, and gate all around (GAA) FET transistors, as well as tunneling FET (TFET) transistors, ferroelectric FET (FeFET) transistors.

In the drawings of the embodiments, signals are represented with lines. Some lines may appear different from others, for example, thicker or hatched, to distinguish from other depicted signals for ease of understanding. Along these lines, some signal lines may have arrows at one or more ends, to indicate a primary direction of information flow. However, such indications are not intended to be limiting. Rather, lines are used in connection with one or more exemplary embodiments in a given figure to facilitate easier understanding of concepts embodied in block, circuit, and/or flow diagrams. Any represented signal, as dictated by design needs or preferences, may actually comprise one or more signals that may travel in either direction and may be implemented with any suitable type of signal scheme, e.g., analog, digital, wired, wireless, upon the platform within which the present disclosure is to be implemented.

As defined herein, the term “processor” means at least one hardware circuit configured to carry out instructions contained in program code. The hardware circuit may be implemented with one or more integrated circuits. Examples of a processor include, but are not limited to, a central processing unit (CPU), an array processor, a vector processor, a digital signal processor (DSP), a field-programmable gate array (FPGA), a programmable logic array (PLA), an application specific integrated circuit (ASIC), programmable logic circuitry, a graphics processing unit (GPU), a controller, and so forth. It should be appreciated that a logical processor, on the other hand, is a processing abstraction associated with a core, for example when one or more SMT cores are being used such that multiple logical processors may be associated with a given core, for example, in the context of core thread assignment.

It should be appreciated that a processor or processor system may be implemented in various different manners. For example, they may be implemented on a single die, multiple dies (dielets, chiplets), one or more dies in a common package, or one or more dies in multiple packages. Along these lines, some of these blocks may be located separately on different dies or together on two or more different dies.

While the flow diagrams in the figures show a particular order of operations performed by certain embodiments of the invention, it should be understood that such order is exemplary (e.g., alternative embodiments may perform the operations in a different order, combine certain operations, overlap certain operations, etc.).

While the invention has been described in terms of several embodiments, those skilled in the art will recognize that the invention is not limited to the embodiments described, can be practiced with modification and alteration within the spirit and scope of the appended claims. The description is thus to be regarded as illustrative instead of limiting.

What is claimed is:

1. An apparatus, comprising:
a level shift circuit including a local low-supply reference node and an input node;
a local reference switch circuit coupled to the local low-supply reference node to provide a first low-supply reference level responsive to the input node transitioning from a first logic state to a second logic state and to provide a second low-supply reference level thereafter before the input node transitions back to the first logic state, wherein the second low-supply reference level is higher than the first low-supply reference level.

2. The apparatus of claim 1, wherein the local reference switch circuit is coupled to a ground node for the first low-supply reference level.

3. The apparatus of claim 2, wherein the local reference switch circuit is coupled to an elevated reference generation circuit for the second low-supply reference level.

4. The apparatus of claim 3, wherein the elevated reference generation circuit includes a diode-connected transistor to generate the second low-supply reference level.

5. The apparatus of claim 3, wherein the local reference switch circuit includes an AND circuit coupled between the ground node and the local low-supply reference node.

6. The apparatus of claim 5, wherein the local reference switch circuit includes an OR circuit coupled between the local low-supply reference node and the elevated reference generation circuit.

7. The apparatus of claim 1, comprising a control circuit including two or more sequentially-coupled delay circuits coupled to the local reference switch circuit to control whether the first or second low-supply reference level is provided to the local low-supply reference node.

8. The apparatus of claim 1, wherein the local reference switch circuit is a first local reference switch circuit coupled to a first branch of the level shift circuit, the apparatus comprising a second local reference switch circuit coupled to a second branch of the level shift circuit.

9. The apparatus of claim 8, wherein the first and second branches are to provide complementary gate drive output signals.

10. An apparatus, comprising:
an input/output (IO) interconnect circuit including at least one transmitter circuit that includes a pre-driver circuit with an input node to receive an input signal with a first high-supply reference limit and an output node coupled to a high-side output transistor, the output node to provide a drive signal with a second high-side reference limit that is higher than the first high-side reference limit;
wherein the pre-driver circuit includes a level shift circuit with a moveable low-supply reference that is to pull down to a first low-supply reference level from a second low-supply reference level when the drive signal transitions to a low state.

11. The apparatus of claim 10, wherein the IO interconnect is part of a double-data rate (DDR) link interface in a field programmable gate array (FPGA) device.

12. The apparatus of claim 10, wherein the pre-driver circuit includes a local reference switch circuit coupled to provide the moveable low-supply reference and is coupled to a ground node for the first low-supply reference level.

13. The apparatus of claim 12, wherein the local reference switch circuit is coupled to an elevated reference generation circuit for the second low-supply reference level.

14. The apparatus of claim 13, wherein the elevated reference generation circuit includes a diode-connected transistor to generate the second low-supply reference level.

15. The apparatus of claim 13, wherein the local reference switch circuit includes an AND circuit coupled between the ground node and the moveable low-supply reference and an OR circuit coupled between the moveable low-supply reference and the elevated reference generation circuit.

16. A system, comprising:
a first integrated circuit (IC) including a first interconnect circuit with at least one transmitter circuit that includes:
a level shift circuit including a local low-supply reference node and an input node;
a local reference switch circuit coupled to the local low-supply reference node to provide a first low-supply reference level responsive to the input node transitioning from a first logic state to a second logic state and to provide a second low-supply reference level thereafter before the input node transitions back to the first logic state, wherein the second low-supply reference level is higher than the first low-supply reference level; and
a second IC including a second interconnect with at least one receiver circuit coupled to the at least one transmitter circuit.

17. The system of claim 16, wherein the first and second interconnect circuits form a double-data rate (DDR) link, and the second IC is a memory device.

18. The system of claim 16, wherein the local reference switch circuit is coupled to a ground node for the first low-supply reference level, and the local reference switch circuit is coupled to an elevated reference generation circuit for the second low-supply reference level.

19. The system of claim 18, wherein the local reference switch circuit includes an AND circuit coupled between the ground node and the local low-supply reference node and an OR circuit coupled between the local low-supply reference node and the elevated reference generation circuit.

20. The system of claim 16, comprising a control circuit including two or more sequentially-coupled delay circuits coupled to the local reference switch circuit to control whether the first or second low-supply reference level is provided to the local low-supply reference node.
